(19) United States
(12) Patent Application Publication
(10) Pub. No.: US 2002/0189086 A1
(43) Pub. Date: Dec. 19, 2002

(54) Grounding assembly and method of producing same

(75) Inventors: Masanori Yamaguchi, Kawasaki (JP); Yoshiaki Hiratsuka, Kawasaki (JP); Hisashi Yoshinaga, Kawasaki (JP)

Correspondence Address: ARMSTRONG,WESTERMAN & HATTORI, LLP, 1725 K STREET, NW., SUITE 1000, WASHINGTON, DC, 20006, US

(73) Assignee: FUJITSU LIMITED, Kawasaki (JP)

(21) Appl. No.: 10/218,458

(22) Filed: Aug. 15, 2002

Related U.S. Application Data
(62) Division of application No. 09/663,937, filed on Sep. 18, 2000.

(30) Foreign Application Priority Data
Oct. 21, 1999 (JP) 11-299077

(51) Int. Cl. H01R 43/00; H05K 3/20

(52) U.S. Cl. 29/825; 29/831

(57) ABSTRACT

A grounding assembly, preventing discharge induced by charging and thereby suppressing the propagation of noise, comprising a grounding member to be electrically connected to grounding terminals of computers and a conductive member surrounding the grounding member and having a predetermined resistance. The resistance value of the conductive member is set to at least a value preventing contact current when another metal body touches the grounding member, for example, at least 2.5×104 Q. Further, the resistance value of the conductive member is set lower than a value where the conductive member is charged with static electricity, for example less than 1.0×109 Q, so the conductive member is not charged with high voltage static electricity. For this reason, the energy required for a discharge does not accumulate in this conductive member and accordingly noise due to static electricity can be suppressed.

### BACKGROUND OF THE INVENTION

1. Field of the Invention

The present invention relates to a grounding assembly and a method of producing a grounding assembly.

Relatively large-sized computer systems are now routinely being installed in ordinary buildings and other structures. Computer systems however are sensitive pieces of equipment which can malfunction or break down due to external noise and other influences. As one means to eliminate such influences, computer systems have been grounded using specially designed grounding wires.

2. Description of the Related Art

In recent years, however, as a tendency toward use of international standards in construction of building grounding installations and reduction of costs, the general practice is becoming to use the same grounding wires as used for elevator power sources and various electrical and electronic apparatuses such as consumer electronics rather than providing special grounding wires designed especially for computer systems.

If using the same grounding wires commonly as described above, it is still necessary to ensure that external noise does not reach the computer system. To deal with this, for example, Japanese Unexamined Patent Publication (Kokai) No. 6-104066 discloses to arrange a grounding plate covered on its outside surface with an insulator and connected to a grounding terminal of a distribution panel under a free access floor in the building. The grounding plate forms a capacitor having a large electrical capacitance with the steel frame of the building facing it across the concrete floor. This enables the high frequency noise propagated from the elevator power source etc. to be led to the ground. Note that the grounding plate is covered by the insulator in order to prevent an unstable noise from entering the grounding plate due to contact of the grounding plate with the steel frame of the building or metal parts electrically connected to it.

It was found however that covering the grounding plate by an insulator created a new problem. Air from an air conditioner under the floor is often circulated under the free access floor where the grounding plate is installed. When the air flows along the surface of the insulator, the surface ends up being charged with static electricity. If the surface of the insulator becomes high in potential due to this static electricity, a discharge is liable to occur to the grounding plate and the resultant noise is liable to be propagated to the computer system through the grounding wire.

Separate from this problem, in order to secure a sufficiently large electrical capacitance in order to prevent the propagation of the noise, the surface area of the grounding plate must be about 1 m². In general, however, floor supports are provided under free access floors at narrow intervals, so there is also the problem that it is difficult to install a grounding plate having a large surface area as it is.

To deal with this, the related art, for example, Japanese Unexamined Patent Publication (Kokai) No. 9-306564 discloses connecting a plurality of small grounding plates by using conductive butterfly hinges or wires to improve the degree of freedom of installation while securing the necessary surface area. Having to connect several grounding plates in the space under a free access floor causes the new problem of troublesome installation. Further, some buildings are not provided with free access floors. In such cases, there is the problem of where to install the grounding plate.

### SUMMARY OF THE INVENTION

Accordingly, an object of the present invention is to provide a grounding assembly preventing discharge induced by charging and thereby suppressing the propagation of noise and a method of producing the same.

Another object of the present invention is to provide a grounding assembly installable regardless of existence of a free access floor.

To attain the above object, the present invention provides a grounding assembly (20) comprising a grounding member (21) to be electrically connected to grounding terminals (31a to 33a) of computers (31 to 33) and a conductive member (22) surrounding the grounding member (21) and having a predetermined resistance. The resistance value of the conductive member (22) is set to at least a value preventing contact current occurring when another metal body touches the grounding member (21) through the conductive member, for example, at least 2.5×10⁴ Ω. Further, the resistance value of the conductive member (22) is set lower than a value where the conductive member (22) is charged with static electricity, for example less than 1.0×10⁹ Ω, so the conductive member (22) is not charged with high voltage static electricity. For this reason, the energy required for a discharge does not accumulate in this conductive member and accordingly noise due to static electricity can be suppressed.

### BRIEF DESCRIPTION OF THE DRAWINGS

The above objects and features of the present invention will be more apparent from the following description of the preferred embodiments given with reference to the accompanying drawings, wherein:

FIG. 1 is a schematic view of the arrangement of a grounding assembly according to a first embodiment of the present invention installed in a building:

FIG. 2 is a perspective view of the grounding assembly of the first embodiment;

FIG. 3 is a partial enlarged view of the configuration of FIG. 2 seen in the arrow direction along a line III-III;

FIG. 4 is a view of a projection piece according to a modification of the first embodiment;

FIG. 5 is a view of an arrangement of installation of the grounding assembly of the first embodiment under a free access floor;

FIG. 6 is a view of another modification; and

FIG. 7 is a perspective view of a grounding assembly according to a second embodiment of the present invention.

### DESCRIPTION OF THE PREFERRED EMBODIMENTS

Preferred embodiments of the present invention will be described in detail below while referring to the attached figures.

The grounding assembly is designed to be installed facing the conductive frame part of a building held substantially at the ground potential and is comprised of a conductive grounding member to be electrically connected to a grounding terminal of an electronic apparatus and a conductive member surrounding the grounding member and having a predetermined resistance value. Here, the resistance value of the conductive member is set to be higher than the value preventing the contact current and to be lower than the value where the conductive member is substantially charged with static electricity.

Since the resistance value of the conductive member is set to be higher than the value preventing the contact current, even if a high voltage is applied to the grounding member, the contact current can be prevented. Further, since the resistance value of the conductive member is set lower than a value where the conductive member is charged with static electricity, the conductive member is not charged with high voltage static electricity. For this reason, the energy required for a discharge does not accumulate in this conductive member and accordingly noise due to static electricity can be suppressed.

The method of producing the grounding assembly according to the present invention comprises the steps of forming a conductive foil-like grounding member, forming a sheet-like conductive member having a predetermined resistance value, and bonding the conductive member to the grounding member so as to surround this. Here again, the resistance value of the conductive member is set to be higher than the value preventing the contact current when another metal body touches the grounding member and to be lower than the value where the conductive member is substantially charged with static electricity.

Due to this, a more easily bendable grounding assembly can be formed. Further, if the grounding assembly is made bendable, the grounding assembly need not be cut and can be installed by bending it to fit in the space under the free access floor. As a result, it becomes possible to install the grounding assembly at any location while maintaining the surface area of the grounding assembly as it is, so the degree of freedom of installation rises.

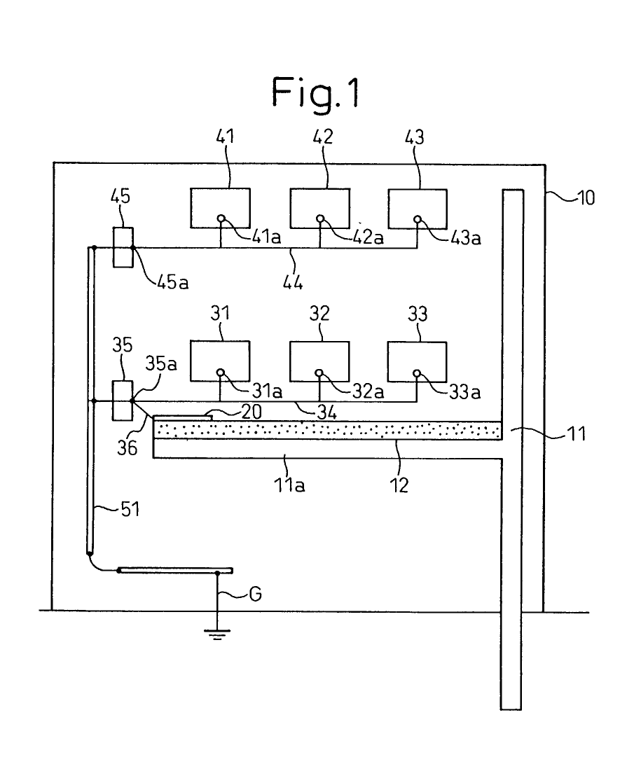

FIG. 1 is a schematic view of the arrangement of the grounding assembly according to a first embodiment of the present invention installed in a building. The building or other structure 10 shown in FIG. 1 is constructed with a steel frame 11 with lower ends buried in the ground. The steel frame 11 has horizontally extending steel floor beams 11a. The steel frame 11 and its steel floor beams 11a comprise a conductive frame held at substantially the ground potential.

Concrete slabs are laid on the top face of the steel floor beams 11a. These form the floor part 12 under the free access floor (not illustrated in FIG. 1). A grounding assembly 20 is placed on the floor part 12.

A computer system including computers 31, 32, and 33 is installed on the story formed by the illustrated floor part 12. Grounding terminals 31a, 32a, and 33a of the computers 31, 32, and 33 are electrically connected to a grounding terminal 35a of a distribution panel of the computer system (hereinafter referred to as a first distribution panel) by wires 34. The grounding assembly 20 is also connected to the grounding terminal 35a of the first distribution panel 35 by a wire 36.

The power source of the elevator, e.g., a motor 41, an electrical appliance, e.g., a refrigerator 42, and a business machine, e.g., a copier 43 are arranged on the same story formed by the illustrated floor part 12 or other story. Here, while a refrigerator and copier were illustrated as an electrical appliance and business machine, the invention is not limited to these. Grounding terminals 41a, 42a, and 43a of the motor 41, refrigerator 42, and copier 43 are electrically connected to a grounding terminal 45a of another distribution panel (hereinafter referred to as a second distribution panel) 45.

The grounding terminal 35a of the first distribution panel 35 and the grounding terminal 45a of the second distribution panel 45 are connected to a grounding bus bar 51 provided in the building 10, while the grounding bus bar 51 is grounded by a known method.

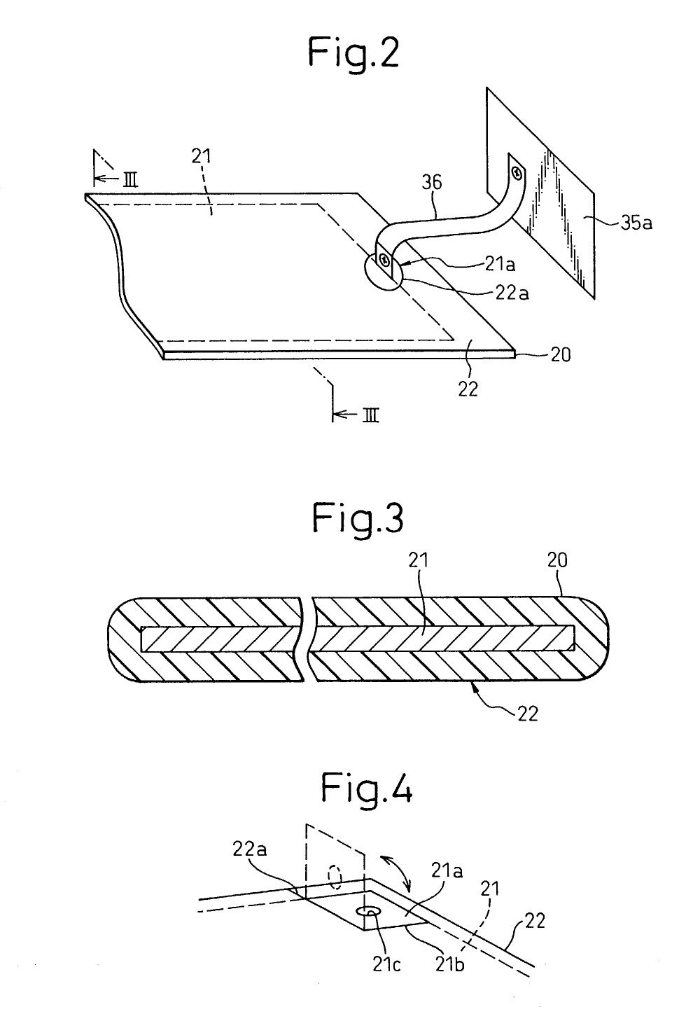

FIG. 2 is a perspective view of a grounding assembly 20 of the present embodiment and shows a state where this is connected to the grounding terminal 35a of the first distribution panel 35. FIG. 3 is a partial enlarged view of the configuration of FIG. 2 seen in a direction indicated by the arrow along a line III-III.

As shown in FIG. 3, the grounding assembly 20 can be easily formed by using an adhesive to bond a conductive member 22 having a high resistance and a thickness of about 0.8 mm to the periphery of a grounding member 21 made of a copper strip having a thickness of about 0.1 mm. By this, the grounding assembly 20 becomes a sheet having a thickness of about 2 mm which can be freely bent in all directions. The grounding assembly 20 according to the present embodiment has a width of 32 cm and a length of 4 m, therefore this grounding assembly 20 can be stored and transported while wound, so is convenient.

The resistance value of the conductive member 22 is preferably made 2.5×10⁴ to 1.0×10⁹ Ω for the following reasons. Such a conductive member 22 can be formed by using for example the material “SKY-16” (resistance value: 8.5×10⁷ Ω) made by Achilles Inc. or the material “Cropoly Mat E-300” (resistance value: 1.6×10⁵ Ω) made by Achilles Inc.

The grounding member 21 can be also made of a material having an electric resistance less than 10 Ω, other than a copper strip, for example gold, silver, aluminum, stainless steel, nickel, brass, magnesium alloy, zinc, or carbon worked thinly to a foil. It is also possible to use a member made by mixing a powder of the above materials into a plastic material (including a rubber material) and form it in a sheet, a member made by forming the above material into wires and directly knitting them, or a member made by coating the above materials on fibers and knitting the fibers.

As shown in FIG. 2, the grounding member 21 has an upright projection piece 21a at a part of one side. The conductive member 22 is cut away around the position of the projection piece 21a to form an opening 22a. The opening 22a is desirably small in order to prevent for example unintentional contact with other metal parts. The projection piece 21a and the grounding terminal 35a of the first distribution panel 35 can be connected by the wire 36.

FIG. 4 is a view of the projection piece 21a according to a first modification of this embodiment. A part of a corner of the conductive member 22 is cut away at just the top surface. Further, a cut 21b is made in part of the grounding member 21. The cut 21b is peeled back to lift up part of the grounding member 21 and thereby form the upright projection piece 21a as indicated by a dotted line. Note that a screw (not shown) may be inserted into the opening 21c formed in the center of the projection piece 21a at the time of connection with the wire 36.

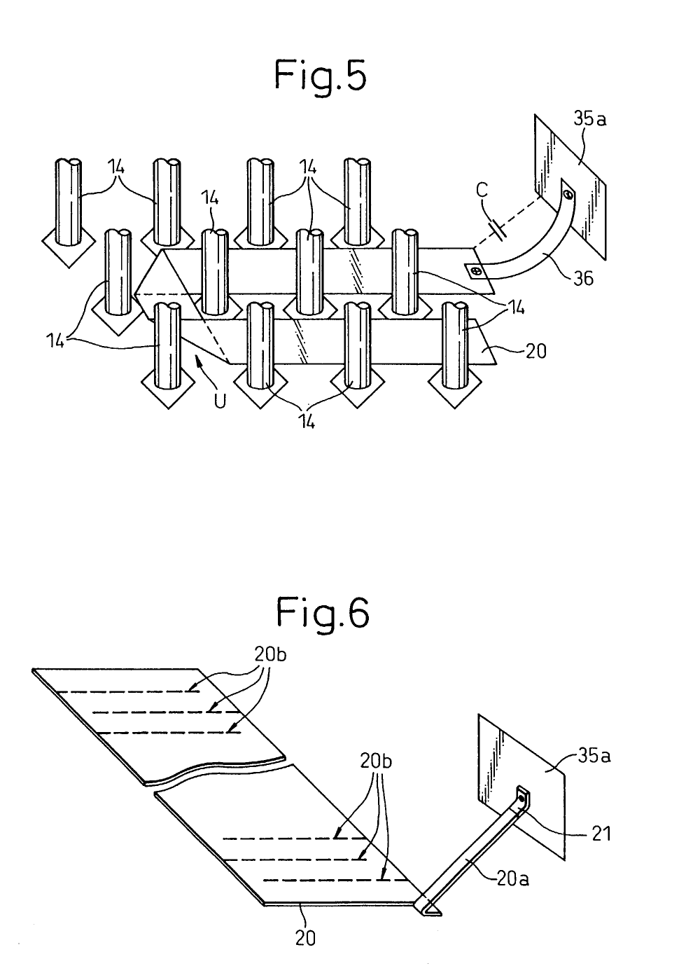

FIG. 5 is a view of an arrangement of installation of the grounding assembly 20 of the present embodiment under the free access floor. In order to secure an electrical capacitance of a magnitude large enough to prevent noise with the steel floor beams 11a of the building 10, the grounding assembly 20 has to have a surface area of the lower surface facing the steel floor beams 11a of about 1 m². On the other hand, the space between the floor supports 14 for supporting the free access floor (not illustrated) is generally about 50 to 60 cm. Accordingly, the grounding assembly 20 must be arranged between these floor supports 14.

According to the present embodiment, the width of the grounding assembly 20 is 32 cm, so the grounding assembly can be arranged between the floor supports 14 with plenty of room. On the other hand, some spaces under the free access floor do not allow a grounding assembly 20 having a length of about 4 m to be installed straight. In such a case, since the grounding assembly 20 of the present embodiment is designed so that it can be freely bent, it can be installed while bent in a U-shape as shown in FIG. 5. Due to this, the degree of freedom of installation of the grounding assembly can be improved. Note that the grounding assembly 20 may be bent not only in a U-shape, but also in for example a Z-shape or an L-shape too. It may be bent to any shape matching the mounting space.

Note that, if connecting the grounding assembly 20 and the grounding terminal 35a of the first distribution panel 35 via a capacitor C as shown by the dotted line of FIG. 5 in place of the wire 36, the grounding assembly 20 and the grounding terminal 35a become insulated in a DC-cut state and become conductive at a high frequency, therefore the high frequency noise entering to the grounding terminal 35a via the grounding bus bar 51 (FIG. 1) can be led to the ground via the grounding assembly 20 while maintaining the grounding terminal 35a at the ground potential, whereby the propagation of the noise to the computer system (31, 32, 33) side can be prevented.

FIG. 6 is a view of another modification. The grounding assembly 20 according to the modification of FIG. 6 has alternate lines of perforations 20b formed inwardly extending from the two sides to the inside. By tearing the grounding assembly 20 up to the middle along a line of these perforations 20b, a strip 20a is formed without detaching from the grounding assembly 20. The strip 20a has the conductivity of the internal grounding member 21 and freely bends, so can be used in place of the wire 36. Namely, by connecting the grounding member 21 exposed on the end of the strip 20a to the grounding terminal 35a of the first distribution panel 35, the wire 36 can be omitted, so the cost can be reduced.

According to the first embodiment explained above, a sufficiently large electrical capacitance is secured between the grounding assembly 20 and the steel floor beams 11a of the structure 10 separated from each other by the concrete floor part 12, therefore the noise reaching the grounding bus bar 51 from the motor 41, refrigerator 42, copier 43, or the like via the second distribution panel 45 can effectively be led to the ground. Further, by setting the resistance value of the conductive member 22 to at least 2.5×10⁴ Ω, there is no contact current when another metal body touches the conductive member 22. If the resistance is high in this way, even if the grounding member 21 touches the steel frame or the floor supports of the free access floor, propagation of the noise to the computer system side can be prevented. Further, the resistance value of the conductive member is set to less than 1.0×10⁹ Ω. Therefore, even if the air of an air conditioner is circulated beneath the free access floor where the grounding assembly 20 is installed, the conductive member 22 is not charged with static electricity, so there is no discharge. Therefore, propagation of noise to the computer system side can be suppressed as much as possible.

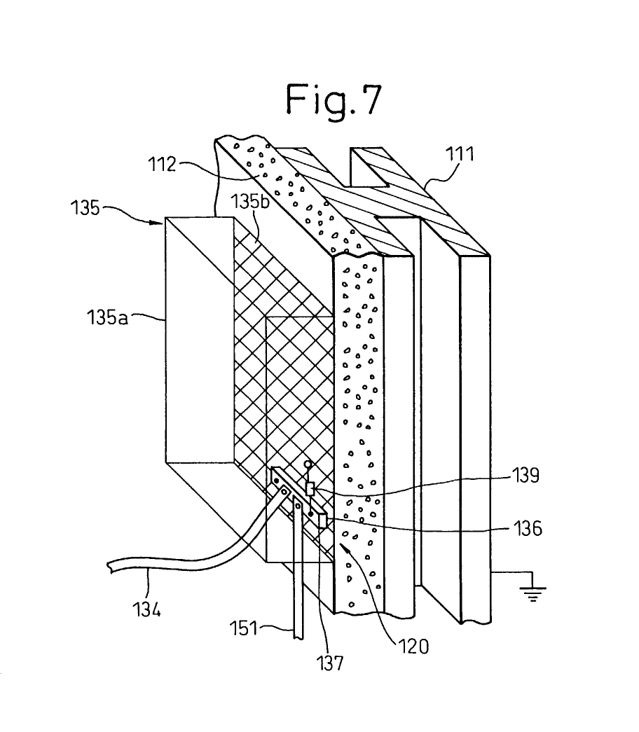

FIG. 7 is a perspective view of a grounding assembly 120 according to a second embodiment of the present invention. In FIG. 7, a distribution panel 135 shown in a perspective state is mounted on a concrete wall 112 made of the building. For easier understanding, the illustration of the parts such as the circuit breakers in the distribution panel 135 is omitted. The distribution panel 135 has a conductive steel housing 135a and is mounted in close contact to the wall 112 at its back surface 135b. It is positioned so that its back surface 135b faces, across the wall 112, a beam of the steel frame 111 with its lower end buried in the ground. In the present embodiment, the back surface 135b constitutes the grounding member.

An insulator 136 made of ceramic or the like is arranged at the bottom of the front surface side of the back surface 135b. A terminal plate 137 is mounted on the front surface of the insulator 136. The terminal plate 137 is insulated from the back surface 135b by the insulator 136. The terminal plate 137 is connected to a grounding bus bar 151 maintained at the ground potential and a grounding wire 134 connected to the grounding terminal (not illustrated) of each computer.

The back surface 135b of the distribution panel 135 and the terminal plate 137 are connected by a capacitor component 139. The back surface 135b and the capacitor component 139 constitute the grounding assembly 120.

According to such a grounding assembly 120, the grounding wire 134 connected to the grounding terminal (not illustrated) of each computer is connected to the grounding bus bar 151, so can maintain the ground potential. Further, the back surface 135b and the terminal plate 137 are DC-cut, therefore even if a high potential metal body (floor support of free access floor or steel frame) contacts the housing 135a of the distribution panel 135, the grounding terminal of each computer can be maintained at the ground potential. Further, when high frequency noise is propagated from the power source of the not illustrated elevator or the like to the terminal plate 137, by propagating such noise to the back surface 135b side via the capacitor component 139, propagation to each computer side can be effectively suppressed.

According to the present embodiment, since use is made of the back surface 135b of a distribution panel 135 having a relatively large surface area as the grounding member, even in for example a building not having a free access floor or a building not having a sufficient installation space, effective grounding of the computer system becomes possible. Namely, even if the space for mounting a large surface area grounding plate is limited, by using the back surface 135b as part of the conductive housing of the distribution panel 135 in place of the grounding plate, a large electrical capacitance can be secured between it and the steel frame 111 of the building, so propagation of the noise to the electric apparatuses can be prevented.

Note that, as a second modification, it may be possible to cover the entire distribution panel 135 or the front surface of the back surface 135b by the conductive member 22 shown in FIG. 3 and thereby utilize the back surface 135b as the grounding member. In such a case, the capacitor component 139 can be omitted and the grounding wire 134 can be directly connected to the back surface 135b. The effects of the present modified embodiment are similar to those of the embodiment mentioned above, so no explanation will be provided.

The present invention was explained by way of embodiments as mentioned above, but the present invention is not limited to these embodiments. Various modifications are possible within the range of the technical concept of the present invention.

Summarizing the effects of the present invention, according to the present invention, there is provided a grounding assembly, designed to be installed facing the conductive frame part of a building held substantially at the ground potential, comprised of a conductive grounding member to be electrically connected to a grounding terminal of an electronic apparatus and a conductive member surrounding the grounding member and having a predetermined resistance value, where the resistance value of the conductive member is set to be higher than the value preventing the contact current when another metal body touches the conductive member and to be lower than the value where the conductive member is substantially charged with static electricity. Further, since the resistance value of the conductive member is set lower than a value where the conductive member is charged with static electricity, the conductive member is not charged with high voltage static electricity. For this reason, the energy required for a discharge does not accumulate in this conductive member and accordingly noise due to static electricity can be suppressed.

The method of producing the grounding assembly according to the present invention comprises the steps of forming a conductive foil-like grounding member, forming a sheet-like conductive member having a predetermined resistance value, and bonding the conductive member to the grounding member so as to surround this, wherein the resistance value of the conductive member is set to be higher than the value preventing the contact current and to be lower than the value where the conductive member is substantially charged with static electricity, so a more easily bendable grounding assembly can be formed. Further, if the grounding assembly is made bendable, the grounding assembly need not be cut and can be installed by bending it to fit in the space under the free access floor. As a result, it becomes possible to install the grounding assembly at any location while maintaining the surface area of the grounding assembly as it is, so the degree of freedom of installation rises.

While the invention has been described by reference to specific embodiments chosen for purposes of illustration, it should be apparent that numerous modifications could be made thereto by those skilled in the art without departing from the basic concept and scope of the invention.

What is claimed is:

1. A method of producing a sheet-like grounding assembly comprising the steps of:
forming a conductive foil-like grounding member,
forming a sheet-like conductive member having a predetermined resistance value set to be higher than a value preventing contact current when another metal body touches the conductive member and to be lower than a value where the conductive member is substantially charged with static electricity, and
bonding the conductive member to the grounding member so as to surround the grounding member.
